(19) United States
(12) Patent Application Publication
(10) Pub. No.: US 2006/0169438 A1
(43) Pub. Date: Aug. 3, 2006

(54) Thermally conductive cover directly attached to heat producing component

(76) Inventors: Christopher G. Malone, Loomis, CA (US); Stephan K. Barsun, Davis, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/046,616

(22) Filed: Jan. 28, 2005

(51) Int. Cl. H05K 7/20

(52) U.S. Cl. 165/80.4; 361/699

(57) ABSTRACT

One embodiment of the apparatus may have: thermally conductive cover coupled to the heat producing component via a single interface; and cooling liquid in direct contact with the thermally conductive cover. One embodiment of the method may have the steps of: coupling a thermally conductive cover to the component via a single interface; and applying a cooling liquid to the thermally conductive cover to cool the component

### BACKGROUND

The present invention relates generally to cooling systems, and more particularly, to cooling systems for heat producing components.

Semiconductor devices produce heat due to leakage currents (steady state) and the switching action of transistors. The amount of power (heat) to be dissipated depends upon the number of circuits in the device, their switching, speed and the load on the circuit. Today's state-of-the-art CMOS devices can produce up to 50 Watts of heat or more for a silicon die that is 2 cm2 in area.

It is important for the cooling system to keep the temperature stable and independent of environmental and operational factors such as air pressure and circuit loading. This has direct implications for the repeatability and stability of the circuit. Cooling effectiveness and efficiency depend on factors such as heat sink design, the properties of the fluid (liquid or air) that is used to transport the heat away from the device and the heat transfer characteristics between the heat sink and the cooling fluid.

In a liquid-cooled test system, the temperature of the liquid cooled plenum is controlled directly by the liquid circulating through it. With good thermal contact to the device, the device temperature can be closely controlled. However, such systems typically have a larger footprint than that of the device.

In contrast, the efficiency of an air-cooled system is limited by its heat sink design, and the speed, direction and uniformity of the airflow. Stability is limited by the formation of “dead spots” or “hot spots” in the air flow. The need for heat sinks and adequate space for air to flow around the components results in lower packing density of components, for example on a printed circuit board. Lower packing density also limits top end speeds and precision because longer propagation delays and larger parasitics from longer signal lines degrade signals.

Thus, there is a need for an apparatus and method that overcome these drawbacks of the prior art.

### SUMMARY

The invention in one embodiment encompasses an apparatus. The apparatus, in one example, that cools a heat producing component may have: thermally conductive cover coupled to the heat producing component via a single interface; and cooling liquid in direct contact with the thermally conductive cover.

Yet another embodiment of the invention encompasses a method. The method in one example may have the steps of: coupling a thermally conductive cover to the component via a single interface; and applying a cooling liquid to the thermally conductive cover to cool the component.

### DESCRIPTION OF THE DRAWINGS

Features of exemplary implementations of the invention will become apparent from the description, the claims, and the accompanying drawings in which:

FIG. 1 depicts an embodiment of the present method and apparatus.

FIG. 2 depicts a prior art liquid cooled embodiment.

FIG. 3 depicts one embodiment of the present method and apparatus.

FIG. 4 depicts a cross-sectional view of an embodiment of the present apparatus.

FIG. 5 depicts a top view of a portion of the FIG. 4 embodiment.

FIG. 6 depicts a cross-sectional view of another embodiment of the present apparatus.

FIG. 7 depicts a top view of a portion of the FIG. 6 embodiment.

FIG. 8 depicts a cross-sectional view of a further embodiment of the present apparatus.

FIG. 9 depicts a top view of a portion of the FIG. 8 embodiment.

FIG. 10 depicts a cross-sectional view of yet another embodiment of the present apparatus.

FIG. 11 depicts a top view of a portion of the FIG. 10 embodiment.

FIG. 12 depicts a flow diagram of an embodiment of the present method.

FIG. 13 depicts a flow diagram of another embodiment of the present method.

### DETAILED DESCRIPTION

In general, some embodiments of the present apparatus that cools a heat producing component may have: thermally conductive cover coupled to the heat producing component via a single interface; and cooling liquid in direct contact with the thermally conductive cover. The thermally conductive cover may be a cold plate or a heat spreader. The heat producing component may be a semiconductor die. Furthermore, the thermally conductive cover may occupy a same footprint as the die.

Some embodiments of the present method for cooling a semiconductor die may have the steps of: providing an exposed area on an upper surface of a heat spreader that is coupled to the semiconductor die; and applying a cooling liquid directly to the exposed area of the upper surface of the heat spreader.

The heat spreader may have sides, and the method may further have the step of coupling a cold plate to the sides of the heat spreader. The cold plate may be structured such that, when the cold plate is coupled to the heat spreader, substantially an entire area of an upper surface of the heat spreader is exposed to the cooling liquid. The cold plate may occupy a same footprint as the die.

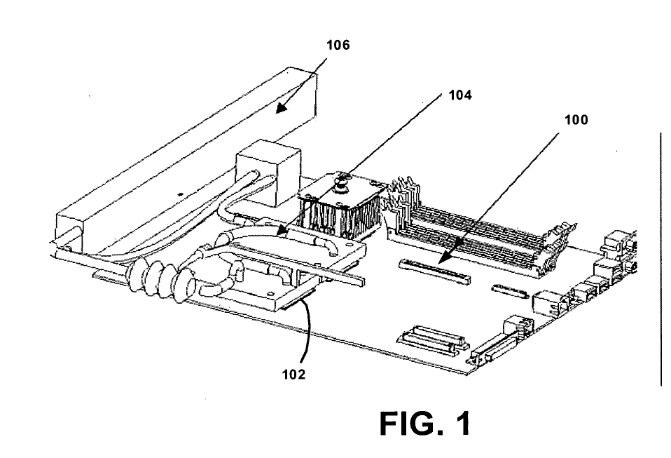

FIG. 1 depicts an embodiment of the present apparatus, in which a liquid cooling loop is used to cool processors or other thermal components. In the FIG. 1 embodiment, a printed circuit board 100 has at least one heat-producing component 102, such as an integrated circuit. A device-to-liquid cooling exchanger 104 is coupled to the heat-producing component 102. The device-to-liquid cooling exchanger 104 is also coupled to a liquid compressor 106. The device-to-liquid heat exchanger 104 transfers heat from the heat-producing component 102 to a cooling liquid. The liquid-to-air heat exchanger 106 removes the heat from the cooling liquid.

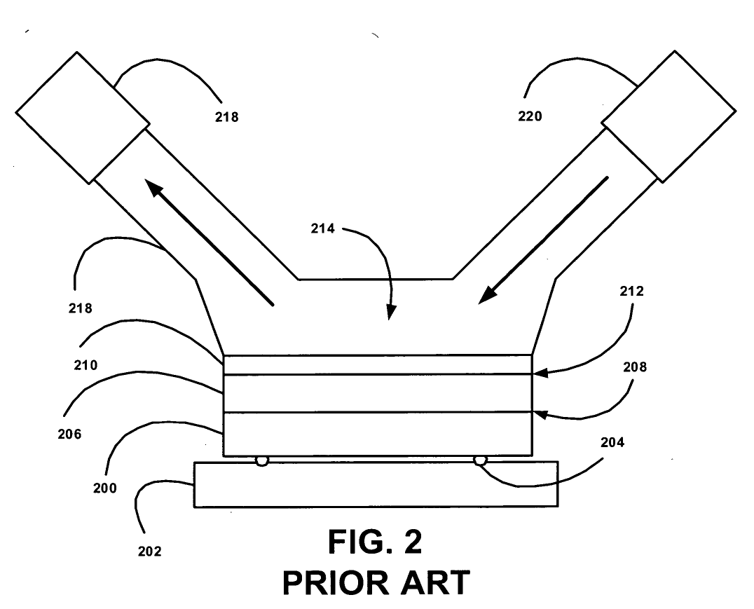

FIG. 2 depicts a prior art liquid cooled example. A typical thermal stackup for a silicon chip has an integrated circuit die 200 that is coupled to a substrate 202, such as a silicon substrate, via at least solder locations 204. The die 200 has a chip lid or cover 206 coupled to a top of the die 200 by a first thermal interface 208. A heat sink or other thermally dissipative device is coupled to a top of the cover 206 via a second thermal interface 212.

In the FIG. 2 example, a cold plate 210 is coupled to a top of the cover 206 via a second thermal interface 212. The second thermal interfacing 212 between the cold plate 210 and the cover 206 is a potential problem area and source of thermal resistance.

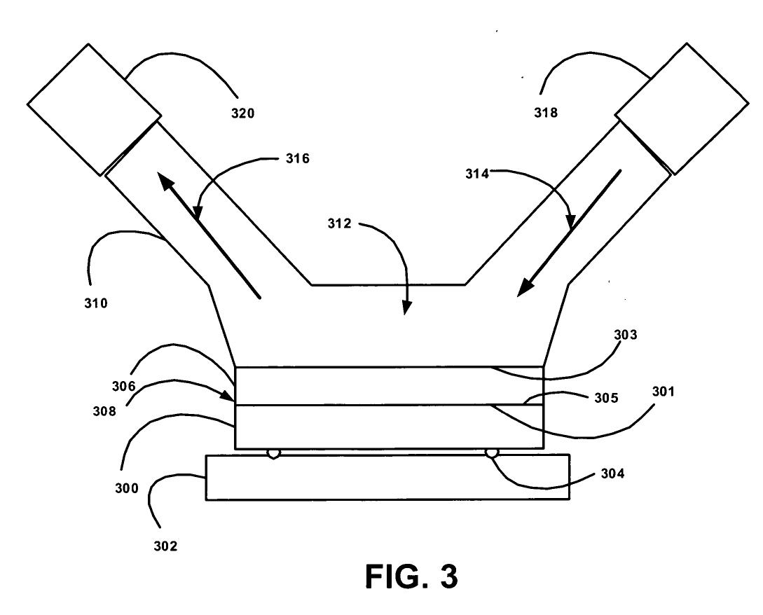

FIG. 3 depicts one embodiment of the present apparatus. This exemplary embodiment of the present apparatus may have: an integrated circuit die 300 (coupled to a substrate 302 via electrical connections 304) having an upper surface 301; a cold plate 306 having an upper surface 303 and a lower surface 305, the lower surface 305 bonded directly to the upper surface 301 of the die 300 via a thermal interface 308; and cooling liquid in direct contact with the upper surface 303 of the cold plate 306. Thus in this embodiment the prior art chip lid or cover is replaced by the cold plate 306. The cold plate 306 may occupy a same footprint as the die 300.

The cooling liquid is contained in a chamber 312 of a housing 310. Input coupling 318 and output coupling 320 connected the housing 310 to the rest of the cooling system. Cooling liquid 314 flows into the chamber 312 where the cooling liquid in the chamber 312 contacts the upper surface 303 of the cold plate 306. The cooling liquid 316 flows out of the chamber 312. As the cooling liquid flows through the chamber 312, heat is transferred from the upper surface 303 of the cold plate 306 to the cooling liquid.

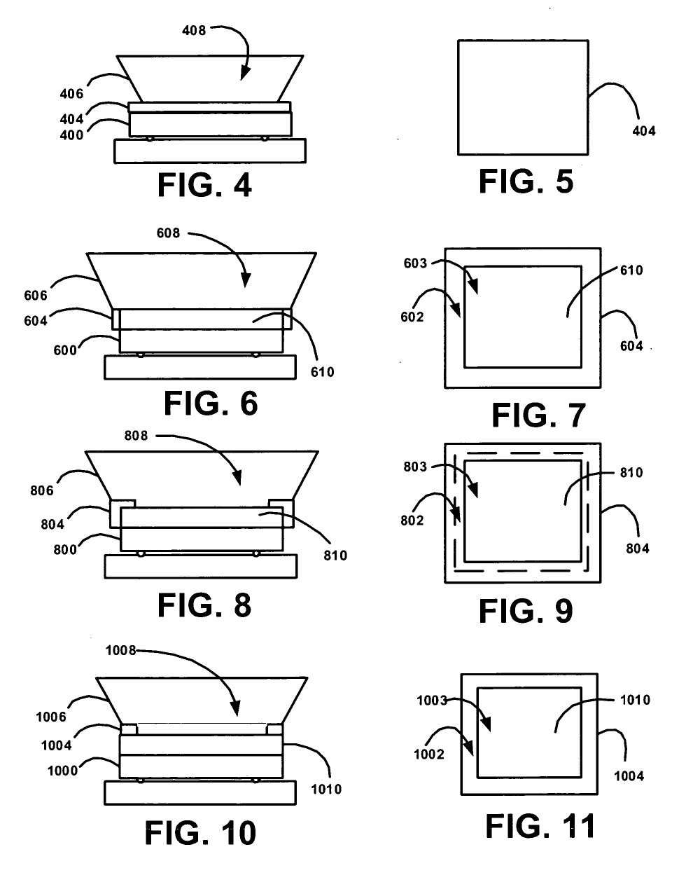

FIG. 4 depicts a cross-sectional view of an embodiment of the present apparatus. This embodiment of the present apparatus may have: an integrated circuit die 400 that has a cold plate 404 coupled directly to the die 400 via a thermal interface; and cooling liquid in direct contact with the cold plate 404. The cooling liquid may be contained in a chamber 408 of a housing 406 coupled to the cold plate 404. The cold plate 404 may occupy a same footprint as the die 400 (see FIG. 5).

FIG. 6 depicts a cross-sectional view of another embodiment of the present apparatus. This embodiment of the present apparatus may have: integrated circuit die 600 that has a heat spreader 610 coupled to the die 600 via a thermal interface; cold plate 604 having an attachment area 602 and an open area 603, the attachment area 602 of the cold plate 604 coupled to the heat spreader 610 such that the open area 603 of the cold plate 604 exposes at least a portion of the upper surface of the heat spreader 610; and cooling liquid in direct contact with the exposed portion of the upper surface of the heat spreader 610. The cooling liquid may be contained in a chamber 608 of a housing 606 coupled to the cold plate 604.

The heat spreader 610 may have sides, and the attachment area of the cold plate 604 may be coupled to the sides of the heat spreader 610, as depicted in FIG. 6. The attachment area of the cold plate 604 may be structured such that, when the cold plate 604 is coupled to the heat spreader 610, substantially an entire area of the upper surface of the heat spreader 610 is exposed to the cooling liquid. Here, again the cold plate 604 may substantially occupy a same footprint as the die 600 (see FIG. 7).

FIG. 8 depicts a cross-sectional view of another embodiment of the present apparatus. This embodiment of the present apparatus may have: an integrated circuit die 800 that has a heat spreader 810 coupled to the die 800 via a thermal interface; a seal 804 having an attachment area 802 and an open area 803, the attachment area 802 of the seal 804 coupled to the heat spreader 810 such that the open area 803 of the seal 804 exposes at least a portion of the supper surface of the heat spreader 810; and cooling liquid in direct contact with the exposed portion of the upper surface of the heat spreader 810. The cooling liquid may be contained in a chamber 808 of a housing 806 coupled to the seal 804. Although this embodiment has both a heat spreader 810 and a seal 804, cooling of the die 800 is effected substantially by the cooling liquid being in direct contact with the heat spreader 810 via the open area 803 of the seal 804. The seal 804 may also be referred to as a cold plate.

In this embodiment, the heat spreader 810 may have sides, and the attachment area of the seal 804 may have a “L” shaped cross-section that overlaps the upper surface of the heat spreader 810, as well as, the sides of the heat spreader 810, as depicted in FIG. 8. The attachment area of the seal 804 may be structured such that, when the seal 804 is coupled to the heat spreader 810, substantially an entire area of the upper surface of the heat spreader 810 is exposed to the cooling liquid. Here, again the seal 804 may substantially occupy a same footprint as the die 800 (see FIG. 9).

FIG. 10 depicts a cross-sectional view of another embodiment of the present apparatus. This embodiment of the present apparatus may have: an integrated circuit die 1000 that has a heat spreader 1010 coupled to the die 1000 via a thermal interface; a seal 1004 having an attachment area 1002 and an open area 1003, the attachment area 1002 of the seal 1004 coupled to a boarder area of the upper surface of the heat spreader 1010 such that the open area 1003 of the seal 1004 exposes at least a portion of the supper surface of the heat spreader 1010; and cooling liquid in direct contact with the exposed portion of the upper surface of the heat spreader 1010. The cooling liquid may be contained in a chamber 1008 of a housing 1006 coupled to the seal 1004.

The attachment area 1002 of the seal 1004 may be structured such that, when the seal 1004 is coupled to the heat spreader 1010, substantially an entire area of the upper surface of the heat spreader 1010 is exposed to the cooling liquid. Here, again the seal 1004 may substantially occupy a same footprint as the die 1000 (see FIG. 11).

Numerous other configurations of the cold plate may be utilized that allow the cooling fluid to directly contact at least a portion of the heat spreader. For example, the cold plate may have a plurality of open areas. The “cold plate” in FIGS. 6-11 may also be formed from a variety of materials that allow the cooling material to directly contact the heat spreader.

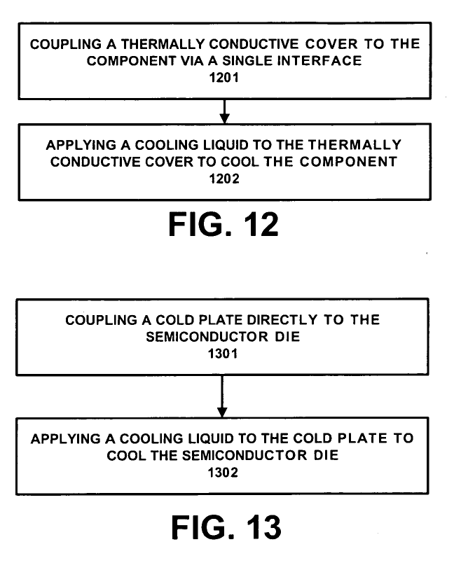

FIG. 12 depicts a general block diagram of one example of the present method. An exemplary embodiment of the method for cooling a component may have the steps of: coupling a thermally conductive cover to the component via a single interface (1201); and applying a cooling liquid to the thermally conductive cover to cool the component (1202). The thermally conductive cover may be a cold plate, or alternatively may be a heat spreader. The component may be a semiconductor die (also referred to as a chip die), for example, and the thermally conductive cover may occupy substantially a same footprint as the die.

FIG. 13 depicts a general block diagram of a further example of the present method. An exemplary embodiment of the method may have the steps of: coupling a cold plate directly to the semiconductor die (1301); and applying a cooling liquid to the cold plate to cool the semiconductor die (1302). The cold plate may occupy a same footprint as the die.

In most applications the liquid must not directly contact the silicon since it will likely boil and therefore have very poor heat transfer characteristics. Direct contact between the cooling liquid and the silicon can be beneficial because it eliminates a source of thermal resistance (the heat spreader). However, power density must be considered. If the power density of the chip is sufficiently high, a pool of liquid will boil and a vapor bubble will form between the silicon (or heat spreader), resulting in poor thermal characteristics. This is called pool boiling. To avoid this, the liquid/vapor is pumped out of the chamber to avoid pool boiling. Alternatively, extended surfaces (fins) may be added to the heat source.

The apparatus in one example may have a plurality of components such as hardware components. A number of such components may be combined or divided in one example of the apparatus. The apparatus in one example may have any (e.g., horizontal, oblique, or vertical) orientation, with the description and figures herein illustrating one exemplary orientation of the apparatus, for explanatory purposes.

Thus, embodiments of the present method and apparatus overcome the drawbacks of the prior art by embodiments that reduce cost due to fewer components, that have improved thermal performance resulting in denser products, and that have reduced footprint of attachment to enable denser component spacing and faster operating frequencies.

The steps or operations described herein are just exemplary. There may be many variations to these steps or operations without departing from the spirit of the invention. For instance, the steps may be performed in a differing order, or steps may be added, deleted, or modified.

Although exemplary implementations of the invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims.

What is claimed is:

1. An apparatus that cools a heat producing component, comprising:
thermally conductive cover coupled to the heat producing component via a single interface; and
cooling liquid in direct contact with the thermally conductive cover.

2. The apparatus according to claim 1, wherein the thermally conductive cover is a cold plate.

3. The apparatus according to claim 1, wherein the thermally conductive cover is a heat spreader.

4. The apparatus according to claim 1, wherein the heat producing component is a semiconductor die, and wherein the thermally conductive cover occupies substantially a same footprint as the die.

5. An apparatus, comprising:
integrated circuit die having an upper surface;
cold plate having an upper surface and a lower surface, the lower surface bonded directly to the upper surface of the die; and
cooling liquid in direct contact with the upper surface of the cold plate.

6. The apparatus according to claim 5, wherein the cold plate occupies a same footprint as the die.

7. An apparatus, comprising:
integrated circuit die having an upper surface;
heat spreader having an upper surface and a lower surface, the lower surface of the heat spreader coupled to the upper surface of the die;
cold plate having an attachment area and an open area, the attachment area of the cold plate coupled to the heat spreader such that the open area exposes at least a portion of the supper surface of the heat spreader; and
cooling liquid in direct contact with the exposed portion of the upper surface of the heat spreader.

8. The apparatus according to claim 7, wherein the heat spreader has sides, and wherein the attachment area of the cold plate is coupled to the sides of the heat spreader.

9. The apparatus according to claim 8, wherein the attachment area of the cold plate is structured such that, when the cold plate is coupled to the heat spreader, substantially an entire area of the upper surface of the heat spreader is exposed to the cooling liquid.

10. The apparatus according to claim 7, wherein the cold plate occupies substantially a same footprint as the die.

11. A method for cooling a component, comprising the steps of:
coupling a thermally conductive cover to the component via a single interface; and
directly applying a cooling liquid to the thermally conductive cover to cool the component.

12. The method according to claim 11, wherein the thermally conductive cover is a cold plate.

13. The method according to claim 11, wherein the thermally conductive cover is a heat spreader.

14. The method according to claim 11, wherein the component is a semiconductor die, and wherein the thermally conductive cover occupies substantially a same footprint as the die.

15. A method for cooling a semiconductor die, comprising the steps of:
providing an exposed area on an upper surface of a heat spreader that is coupled to the semiconductor die; and
applying a cooling liquid directly to the exposed area of the upper surface of the heat spreader.

16. The method according to claim 15, wherein the heat spreader has sides, and wherein the method further comprises coupling a cold plate to the sides of the heat spreader.

17. The method according to claim 16, wherein the cold plate is structured such that, when the cold plate is coupled to the heat spreader, substantially an entire area of an upper surface of the heat spreader is exposed to the cooling liquid.

18. The method according to claim 17, wherein the cold plate occupies substantially a same footprint as the die.

19. A method for cooling a semiconductor die, comprising the steps of:
coupling a cold plate directly to the semiconductor die; and
applying a cooling liquid to the cold plate to cool the semiconductor die.

20. The method according to claim 19, wherein the cold plate occupies substantially a same footprint as the die.
